(19) United States
(12) Patent Application Publication
(10) Pub. No.: US 2015/0207478 A1
(43) Pub. Date: Jul. 23, 2015

(54) Adjusting Controls of an Audio Mixer

(71) Applicant: Sven Duwenhorst, Hamburg (DE)

(72) Inventor: Sven Duwenhorst, Hamburg (DE)

(21) Appl. No.: 12/059,946

(22) Filed: Mar. 31, 2008

(51) Int. Cl. H03G 3/00

(52) U.S. Cl. CPC H03G 3/00

(57) ABSTRACT

Systems, methods, and computer program products relating to a user interface for mixing audio signals. In one embodiment, a method includes displaying in a user interface multiple source icons and a manipulator, each source icon representing a separate one of multiple audio sources, each audio source having an output level, receiving a first input modifying a position of the manipulator in the user interface, and determining gain control parameters of an audio mixer to adjust the output levels of each of the multiple audio sources according to the positions of the manipulator and the source icons relative to a reference center in response to the first input. Other embodiments include systems and computer program products.

### BACKGROUND

The present disclosure relates to mixing audio signals.

Audio signals can be provided by a multitude of audio sources. Examples include audio signals from an FM radio receiver, a compact disc drive playing an audio CD, a microphone, or the audio circuitry of a personal computer. The process of modifying the intensity of multiple audio signals in relation to each other and in relation to other audio signals and combining audio signals is referred to as mixing. A device for such a purpose is referred to as a mixer or an audio mixer, and a certain state of the mixer denoting the intensity of multiple audio signals is referred to as mix.

Generally, an audio mixer has a number of input channels. A mixer generally also has a number of output channels and can selectively route the audio signals from the input channels to one or more output channels. In the mixer, audio signals can be conditioned according to parameters specified by a user. Conditioning may include, for example, adjusting the signal intensity (i.e., the audio source output level) of the overall audio signal or adjusting the signal intensity in a specified frequency range. Parameters may include, for example, values for applying a gain to an audio signal, i.e., increasing or decreasing the overall intensity of the signal, or values for adjusting the signal intensity over a specified frequency range.

An audio mixer generally has a number of faders, also known as sliders or attenuators, each controlling the intensity of an audio signal on an input channel, or a group of input channels. This structure exists in software as well as in hardware mixers. Generally, to adjust both the individual intensities of the audio signals and the overall signal intensity of a mix, several adjustments of each fader are necessary in order to achieve the desired result, i.e., setting the intensity of each signal at a desired level in relation to the other audio signals and setting the combined audio signal of all the audio sources, i.e., the overall signal intensity.

Usually, interaction with a user interface of a software mixer involves a cursor controlled through a pointing device, e.g., a mouse, trackball, touchpad, or joystick. Adjustments to a slider control type mixer are made by positioning the cursor over the knob of a graphic representation of a fader, holding down a button of the pointing device, moving it to the desired position, and releasing the button. Another kind of input device may be employed, e.g., a keyboard or keypad. In any case, several adjustments of the faders are necessary for setting the intensity of a number of audio signals relative to each other and for setting the overall signal intensity.

### SUMMARY

This specification describes technologies relating to user interfaces for defining a mixing of audio signals.

In general, one aspect of the subject matter described in this specification can be embodied in methods that include the actions of displaying in a user interface multiple source icons and a manipulator, each source icon representing a separate one of multiple audio sources, each audio source having an output level, the manipulator and each source icon having a displayed position; receiving a first input modifying a position of the manipulator in the user interface; and determining gain control parameters of an audio mixer to adjust the output levels of each of the multiple audio sources according to the positions of the manipulator and the source icons relative to a reference center in response to the first input. Other embodiments of this aspect include corresponding systems, apparatus, and computer program products configured to perform the operations of the methods.

These and other embodiments can optionally include one or more of the following features. First, setting the output level of an audio source includes: setting a reference distance for each of the audio sources to the distance between the corresponding source icon and the reference center; determining a ratio between the reference distance of the source icon and the distance between the source icon and the projection of the manipulator on a line passing through the source icon and the reference center; and determining gain control parameters of the audio mixer to set the output level according to the ratio and a maximum gain factor. Second, setting the output level of an audio source includes: setting a reference distance for each one of the audio sources to the distance between the corresponding source icon and the reference center; determining a first distance by a product of a second distance and the cosine of the subtraction of a first angle value and a second angle value, the second distance being defined by the distance between the manipulator and the reference center, the first angle being defined by the angle between a horizontal reference axis through the reference center and a radial line through the reference center and the source icon, and the second angle being defined by the angle between the horizontal reference axis and a radial line through the reference center and the manipulator; and determining gain control parameters of the audio mixer to set the output level according to the product of the first distance and a maximum gain factor. Third, the source icons are equidistant from the reference center. Fourth, at least one of the source icons represents an audio source that includes multiple input channels. Fifth, setting the output level of an audio source includes: receiving an input setting a value for a generic reference distance; determining the ratio between the generic reference distance and the distance between the corresponding source icon and the manipulator; and determining gain control parameters of the audio mixer to adjust the output level according to the ratio and a maximum gain factor. Sixth, the methods further include the actions of receiving an input grouping one or more audio sources into distinct groups; and assigning to each distinct group an independent manipulator element. Seventh, the methods further include the actions of receiving a second input modifying the position of one or more of the source icons; and updating the gain control parameters of the audio mixer according to the positions of the manipulator and the source icons in response to the second input.

Particular embodiments of the subject matter described in this specification can be implemented to realize one or more of the following advantages. The audio signals of a number of audio sources can be mixed simultaneously by moving (clicking and moving) the manipulator relative to the audio source icons in the display area within the user interface. The ability to concurrently adjust the signal intensity of all audio sources, for example, with one movement of the pointing device, substantially reduces the number of input operations needed to control the mixer.

In some cases, increasing the signal intensity of an audio source decreases the signal intensity of other audio sources. Thus, there is no increase in the combined signal intensity, as there would be if only the signal intensity of a single source were adjusted at a given time.

The spatial relationship between the graphic elements in the user interface gives an easily understood representation of the current settings of the mixer because of a correlation between the spatial relationships and the parameterization of the audio mixer. In some implementations, for example, audio signals from sources represented by elements close to the manipulator element are amplified, and audio signals from sources represented by elements farther away from the manipulator element are attenuated. This facilitates intuitive, quick, and easy mixing.

The user interface can additionally feature the display of a conventional fader interface, in order to display the current settings of the mixer in a conventional way or to facilitate concurrent use of conventional mixing controls if required by the user or application.

The details of one or more embodiments of the invention are set forth in the accompanying drawings and the description below. Other features, aspects, and advantages of the invention will become apparent from the description, the drawings, and the claims.

### BRIEF DESCRIPTION OF THE DRAWINGS

FIG. 1 is a flowchart of an example method for setting output levels of multiple audio sources.

FIG. 2A illustrates an example user interface for an audio mixer.

FIG. 2B illustrates an example way to determine desired output levels.

FIG. 2C illustrates an example way to determine desired output levels.

FIG. 2D illustrates example mappings.

FIG. 3 illustrates an example user interface for an audio mixer with multiple groups of audio sources.

FIG. 4 illustrates an example user interface for an audio mixer also displaying conventional fader controls user interface.

FIG. 5 is a block diagram of an example system.

Like reference numbers and designations in the various drawings indicate like elements.

### DETAILED DESCRIPTION

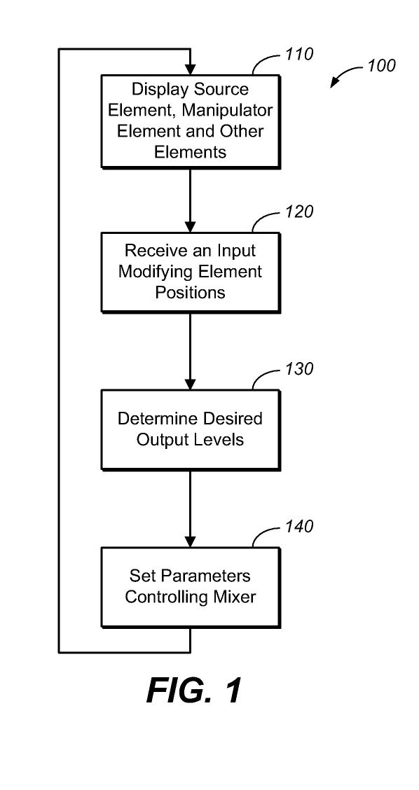

FIG. 1 shows a flowchart of an example method 100 for controlling an audio mixer. For convenience, the method 100 will be described with reference to a system that performs the method 100. The system can be, for example, a digital audio workstation (“DAW”).

The system displays (110) in a display area of a user interface graphic elements (which will be referred to as “icons”) representing controls and audio sources. In some implementations, additional graphic elements may be displayed, e.g., positioning or orientation guides or other auxiliary elements. Graphics representing distinct kinds of elements, for example, audio sources and control elements, are visually distinguishable, e.g., by a different color or shape. In some cases, elements of the same type may also be visually distinguishable, for example, in case of grouping of audio sources.

The system receives (120) an input from a user modifying the position of one or more of the graphic elements, for example, through the use of a pointing device, e.g., a mouse, trackball, touchpad, or joystick.

The system determines (130) a desired intensity for each of the audio signals according to the positions of the graphic elements in the user interface.

The system sets (140) parameters controlling an audio mixer according to the desired intensities.

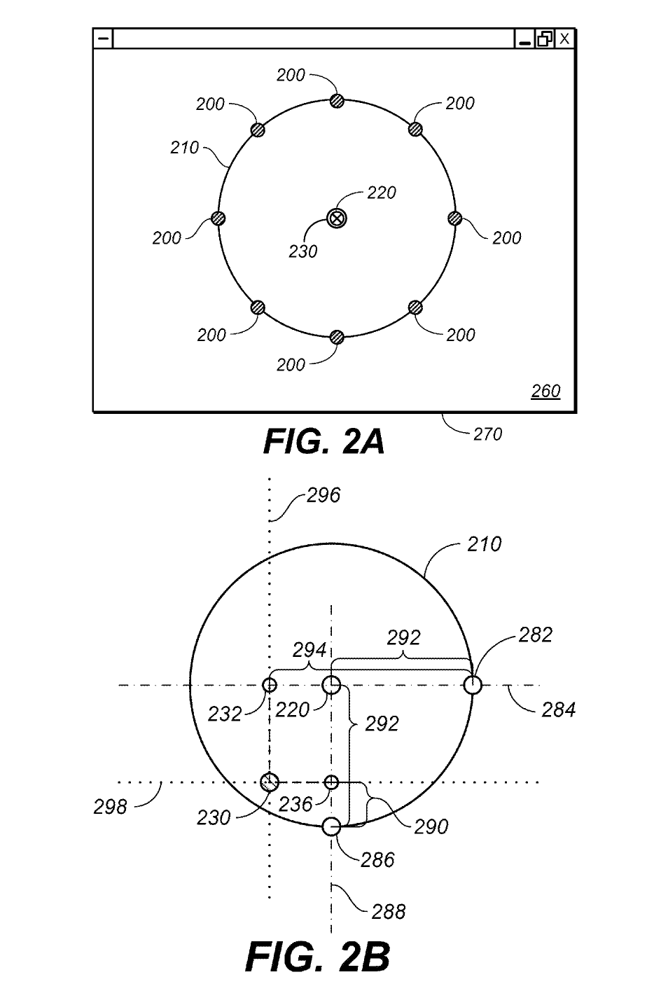

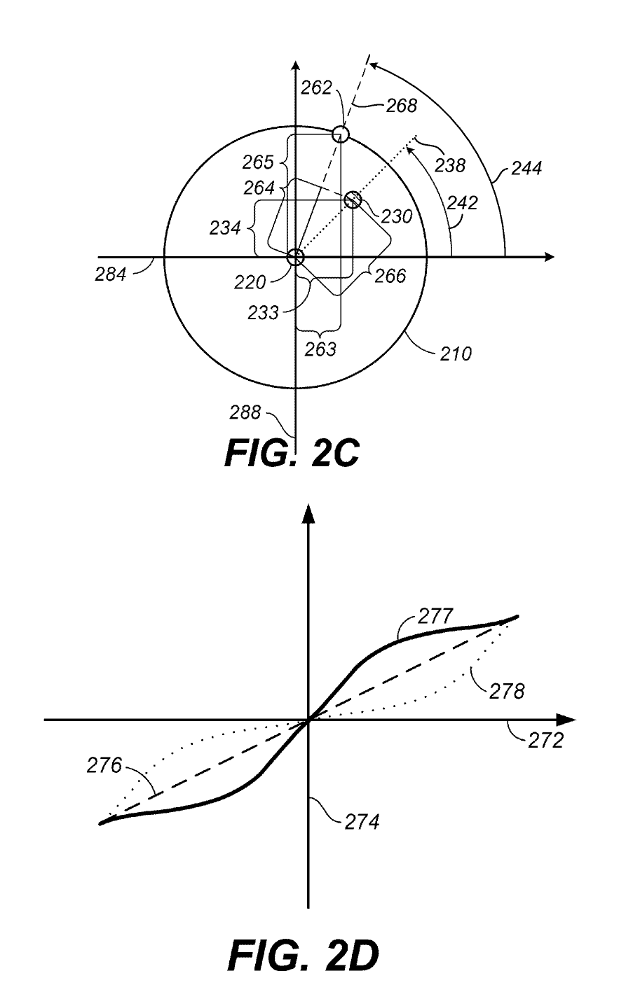

FIG. 2A illustrates an example user interface 270 for an audio mixer. A circle 210 with a center 220 is displayed within a display area 260 of the user interface 270. The audio sources are represented in the interface by source icons, in this example by dots 200, positioned on the circle 210. The center 220 of the circle and a manipulator 230 are represented in a similar but distinguishable way (e.g., by a different color or shape) and are positioned differently. The center 220 is fixed at the center of the circle 210, and the manipulator 230 is positioned within the display area 260. In this example, as a default initial position, the manipulator 230 is located at the center 220. Generally, the manipulator 230 can be positioned freely by a user within the display area 260. In this example, the dots 200 are distributed evenly around the circle 210, and the manipulator 230 is located at the same position as the center 220. In some implementations, the manipulator 230 is not permitted to be positioned outside the circle 210. In some implementations, an audio source can be a grouping of multiple input channels, for example, a grouping of all vocal channels or all percussion channels or all bass channels; in other implementations, each audio source corresponds to a single input channel in the mixer.

The user can move the manipulator 230 to indicate a desired mix. The mixer is controlled to raise the output levels of audio sources closer to the manipulator 230 by a certain amount, and to lower the output levels of audio sources that are farther away from the manipulator 230 by a certain amount. In both cases, the amount is determined by the position of the manipulator and the dots relative to the center, which may be referred to for this reason as the reference center. Thus, the output levels of all audio sources can be modified in one motion of a pointing device without the need for selection or manipulation of a number of individual controls (e.g., one for each source) in a user interface. By easy and intuitive motion of the manipulator, the user can raise individual output levels of some audio sources, while others are not or barely modified, and others are lowered.

As illustrated in FIG. 2B, the desired output levels may be determined using the following formula:

$${g}_{s} = {g}_{ma x} \frac{( {d}_{c} - {d}_{m} )}{{d}_{c}}$$

In this example, the output level gₛ of the source associated with the icon 286 located on the circle 210 is equal to the product of a factor gₘₐₓ, defining maximum gain, and the ratio (d_{c}−dₘ)/d_{c} based on the two distance values, d_{c} (292) and dₘ (290). The distance value d_{c} (292) is defined by the distance between the icon 286 and the center 220. The distance value dₘ (290) is defined by the distance between the icon 286 and the perpendicular projection 236 of the manipulator 230 on a line 288, that passes through the icon 286 and the center 220. The circle 210 may be a unit circle, in which case the distance value d_{c} (292) is 1. For example, a ratio greater than 0 can lead to an amplified signal and a ratio smaller than 0 can lead to an attenuated signal. The output level of the source associated with icon 282 is determined in an analogous way. Additionally, moving the manipulator 230 along the line 298 does not lead to a modification of the output level of the source associated with the icon 286. Similarly, moving the manipulator 230 along the line 296 does not modify the output level of the source associated with icon 282. The elements 232, 236, 284, 288, 296, and 298 are shown for illustration purposes and are generally not displayed in the user interface. In this example, the distance d_{c}, i.e., the radius of the circle 210, defines a reference distance. In this case, the reference distance is the same for all source icons.

In some implementations, a generic reference distance may be set by the user explicitly. In these cases, e.g., where the reference distance of a source icon is not, or cannot be, defined in relation to a circle or a reference center, determining the output levels may include determining the direct distances between source icons and the manipulator and may further include a ratio in which the generic reference distance is used in place of the reference distance described above.

In some implementations, each source icon may have an individual reference distance to the center, e.g., when the source icons are not positioned on a circle, e.g., when they are positioned on an ellipse.

In some implementations, as illustrated in FIG. 2C, the desired output levels may be determined using the following formula:

gₛ=gₘₐₓdₛ

with dₛ=cos(αₛ−αₘ)d, d=\sqrt{xₘ²+yₘ²}, αₛ atan 2 (yₛ, xₛ), and αₘ=atan 2 (yₘ,xₘ).

In this example, the output level gₛ of the source associated with the icon 262 located on a unit circle 210 is equal to the product of the factor gₘₐₓ, defining maximum gain, and the distance dₛ 264. The distance dₛ 264 is determined from the distance d 266 and the angles αₛ 244 and αₘ 242. The angle αₛ 244 is determined from the distances xₛ 263 and yₛ 265. The angle αₘ 242 is determined from the distances xₘ 233 and yₘ 234. The atan 2 function is the C-style two argument arctangent function that calculates the arctangent of y/x with a range of (−π, π] and uses the signs of both arguments to determine the result. The following elements are shown for illustration purposes and are generally not displayed in the user interface: x-axis 284 and y-axis 288, angles 242 and 244, radial lines 238 and 268, and elements 233, 234, 264, 265, and 266.

In some implementations, distances may be mapped to gain values in different ways, e.g., as illustrated in FIG. 2D, which shows a linear mapping 276 and two nonlinear mappings 277, 278 from distance values on the x-axis 272 to gain values on the y-axis 274.

Output levels can be calculated in other ways as well, for example using other distances or distance relations, or using nonlinear equations.

The positions of the graphic elements give an immediate view of the mixer state. In FIG. 2A, that the manipulator 230 is equidistant from each of the dots 200 indicates that the output levels of all sources are the same and they are neither amplified nor attenuated.

The user can further indicate the desired mix by moving the dots 200 representing the audio sources along the circle 210. Output levels of audio sources whose icons are at identical positions are adjusted identically. Output levels of audio sources whose icons are or positioned close together are adjusted in a similar way. Accordingly, output levels of audio sources whose icons are positioned far apart are adjusted differently.

In some implementations, the adjustment of output levels may be constrained to be within a range defined by a value for maximum amplification and a value for maximum attenuation (for example, 12 dB and −12 dB). Other ranges or inverted ranges may be used. In the example of FIG. 2A, if the manipulator 230 is positioned at the same position as one of the dots 200, the output level of the corresponding source is raised or amplified by the maximum amount. Likewise, if the manipulator 230 is positioned to point symmetrically opposite to one of the dots 200, with the center 220 as the center of the symmetry, then the output level of the corresponding source is lowered or attenuated by the maximum amount.

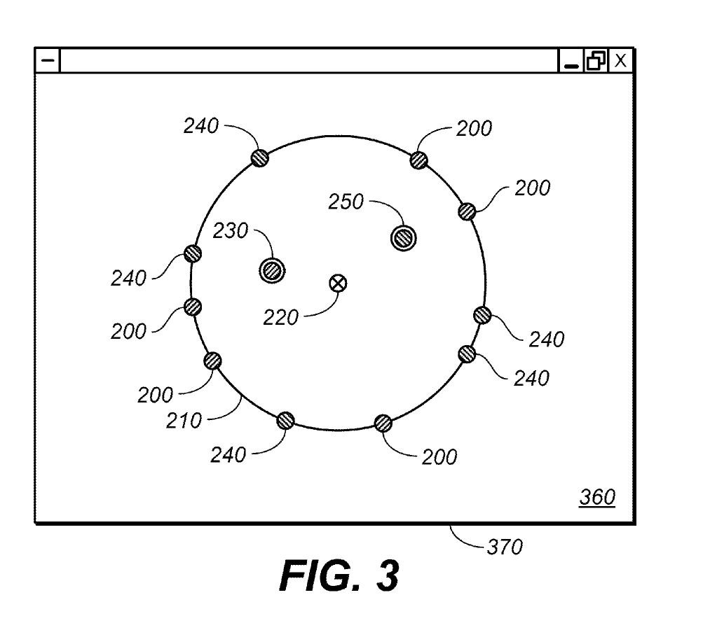

FIG. 3 illustrates an example user interface 370 for an audio mixer with multiple groups of audio sources. In this example, a circle 210 with a center 220 is displayed within a display area 360 of the user interface 370. In this example, audio sources are grouped by the user and the dots 200, 240 representing audio sources from different groups are distinguishable (e.g., by a different color or shape), and a separate manipulator 230, 250 is assigned to each of the groups 200, 240. The manipulators 230, 250 are visually associated with their respective group in order to enable the user to discern which manipulator to operate to control the mixing of a certain group of audio sources. In FIG. 3, various types of fill represent different colors of the graphic elements. Here, the manipulator 230 is assigned to the audio sources represented by the dots 200 and the manipulator 250 is assigned to the audio sources represented by the dots 240.

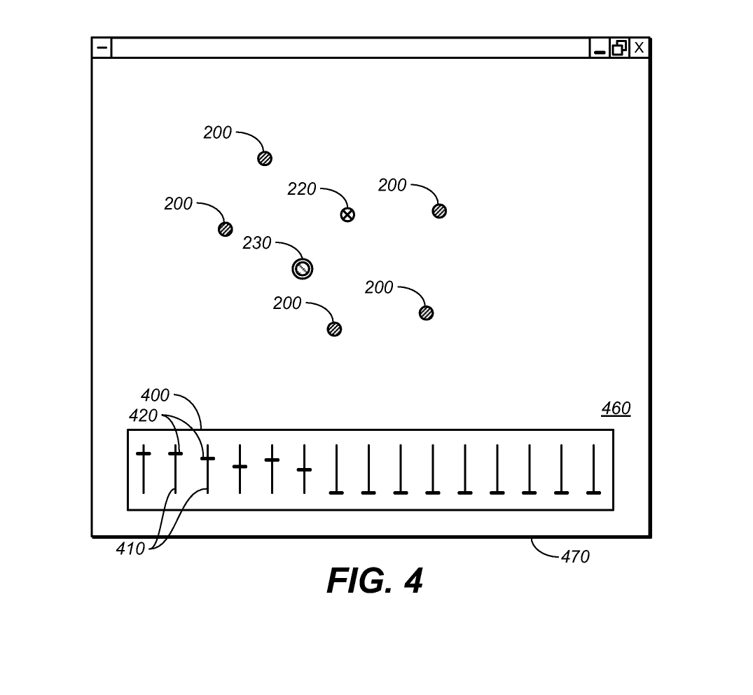

FIG. 4 illustrates an example user interface 470 for an audio mixer also displaying conventional fader controls user interface 400. In this example, a conventional mixer user interface 400 with slider controls 410 is also displayed in a display area 460 within the user interface 470. In this example, the dots 200 are not constrained to be positioned on a predetermined path, e.g., the circle 210 discussed in the description of FIG. 2A. In addition, in implementations corresponding to this example, the dots 200 and the manipulator 230 can be moved freely within the display area 460.

The modifications of the graphic elements in the user interface 470 are reflected in the conventional mixer user interface 400 and vice versa. In this example, the conventional mixer user interface 400 features a separate fader control 410 for each audio source and, optionally, an additional fader control 410 for each group of audio sources. Thus, moving one of the dots 200 (representing an audio source also associated to one of the fader controls 410) towards the assigned manipulator 230 leads to an increased setting on the respective fader control 410. Moving the same dot away from the manipulator 230 has the opposite effect.

In some implementations, some specific settings of fader controls in the conventional mixer user interface 400 cannot be mapped to the user interface, e.g., if the user interface 400 is combined with, or integrated into, the user interface 270 illustrated in FIG. 2. In this example, e.g., the icons 200 may be positioned on the circle 210 in a way that constrains the possible settings of fader controls 410 in the mixer user interface 400 (analogous to FIG. 4). Several solutions for situations like this are possible, e.g., reverting to a last setting of the fader controls 410 which can be mapped to the mixer in the user interface 270.

Implementations of a user interface can vary in a number of particulars from what has been described to accommodate user preference, application requirements, or other considerations. For example, the user interface may permit the icons representing audio sources to be distributed unevenly around the center. When the user places some of the audio source icons close together, the signals from the corresponding sources are adjusted in a similar way. Audio signals represented by icons located at identical positions are adjusted identically. In addition, in some implementations, the dots may be ordered by one or more properties, grouped by type of audio source, and so on. For example, in implementations where the audio sources are tagged by metadata defining properties, the properties can be used to group the dots representing the sources. Such groups may be associated with distinct respective manipulators. Such groups may optionally be displayed in separate areas having their own centers in the user interface so that the icons and manipulators are not visually entangled.

In addition, a shape other than a circle may be used to position the source icons, and the shape may or may not be displayed to the user. If the shape is displayed, the display of the center may be optional. Shapes may be of different kinds, e.g., an ellipse, a polygon, or other closed convex paths may be used. The use of a shape is optional, in that in some implementations the source icons may optionally be allowed to be placed in a display area in arbitrary positions relative to a center.

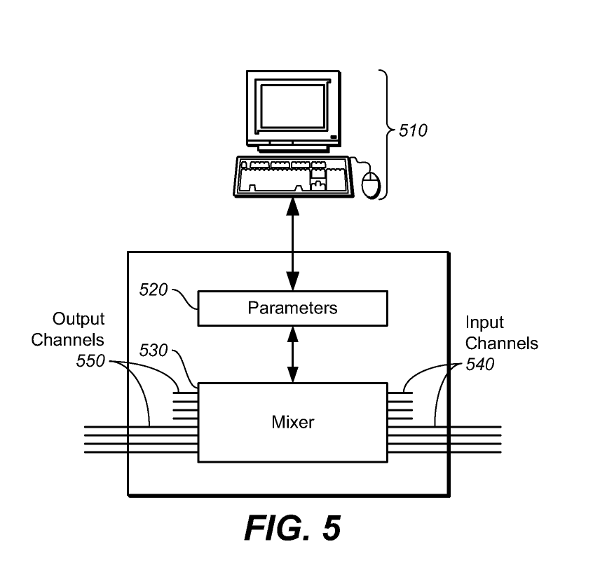

FIG. 5 is a block diagram of an example system. In this example, the user interface is generated by software running on a computer 510 that has conventional display, keyboard and pointing devices and supports a conventional graphical user interface. Using this software, a user interacts with the user interface as described above and the software generates parameters 520 that are provided as inputs to the mixer 530 to control the mixing of signal received by the mixer 530 on input channels 540 to produce a mixed signal or multiple mixed signals on one or more respective output channels 550. Such parameters can be provided to the mixer 530 using, for example, a MIDI protocol, an Open Sound Control protocol, an IEEE 1394 protocol, a USB protocol or any other protocol to transfer information between the hardware and the software either asynchronously or isochronously. Alternatively, and more commonly, the audio mixer itself is implemented in DAW software running on the computer 510 implementing the user interface or on a computer in communication with it, and the audio inputs and outputs are realized as digital audio data.

Generally, the matching of audio sources and mixer parameters with icons in the user interface can be done in any of the ways well known in the domain of user interfaces, and need not be described further.

Embodiments of the subject matter and the functional operations described in this specification can be implemented in digital electronic circuitry, or in computer software, firmware, or hardware, including the structures disclosed in this specification and their structural equivalents, or in combinations of one or more of them. Embodiments of the subject matter described in this specification can be implemented as one or more computer program products, i.e., one or more modules of computer program instructions encoded on a computer-readable medium for execution by, or to control the operation of, data processing apparatus. The computer-readable medium can be a machine-readable storage device, a machine-readable storage substrate, a memory device, a composition of matter effecting a machine-readable propagated signal, or a combination of one or more of them. The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. A propagated signal is an artificially generated signal, e.g., a machine-generated electrical, optical, or electromagnetic signal, that is generated to encode information for transmission to suitable receiver apparatus.

A computer program (also known as a program, software, software application, script, or code) can be written in any form of programming language, including compiled or interpreted languages, and it can be deployed in any form, including as a stand-alone program or as a module, component, subroutine, or other unit suitable for use in a computing environment. A computer program does not necessarily correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio player, a Global Positioning System (GPS) receiver, to name just a few. Computer-readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input.

Embodiments of the subject matter described in this specification can be implemented in a computing system that includes a back-end component, e.g., as a data server, or that includes a middleware component, e.g., an application server, or that includes a front-end component, e.g., a client computer having a graphical user interface or a Web browser through which a user can interact with an implementation of the subject matter described is this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), e.g., the Internet.

The computing system can include clients and servers. A client and server are generally remote from each other and typically interact through a communication network. The relationship of client and server arises by virtue of computer programs running on the respective computers and having a client-server relationship to each other.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the invention have been described. Other embodiments are within the scope of the following claims. For example, the actions recited in the claims can be performed in a different order and still achieve desirable results.

What is claimed is:

1. A computer-implemented method comprising:
displaying in a user interface multiple source icons and a manipulator, each source icon representing a separate one of multiple audio sources, each audio source having an output level, the manipulator and each source icon having a displayed position;
receiving a first input modifying the position of the manipulator in the user interface;
in response to receiving the first input, determining gain control parameters of an audio mixer to adjust the output levels of each of the multiple audio sources, the gain control parameters of the audio mixer determined according to a maximum gain factor and a perpendicular projection of the position of the manipulator onto each line of a plurality of lines, each line of the plurality of lines connecting a corresponding one of the positions of the source icons to a reference center;
receiving an input grouping one or more audio sources into distinct groups; and
assigning to each distinct group an independent manipulator element.

2. The computer-implemented method of claim 1, wherein adjusting the output level of an audio source comprises:
setting a reference distance for each of the audio sources to a distance between the corresponding source icon and the reference center;
determining a ratio between the reference distance of the source icon and a distance between the source icon and the perpendicular projection of the manipulator on the line passing through the source icon and the reference center; and
determining gain control parameters of the audio mixer to set the output level according to the ratio and the maximum gain factor.

3. The computer-implemented method of claim 1, wherein adjusting the output level of an audio source comprises:
determining a first distance by a product of a second distance and the cosine of a difference between a first angle value and a second angle value, the second distance being defined by a distance between the manipulator and the reference center, the first angle value being defined by an angle between a reference axis through the reference center and the line through the reference center and the source icon, and the second angle value being defined by an angle between the reference axis and a radial line through the reference center and the manipulator; and
determining gain control parameters of the audio mixer to set the output level according to the product of the first distance and the maximum gain factor.

4. The computer-implemented method of claim 1, where the source icons are equidistant from the reference center.

5. The computer-implemented method of claim 1, wherein at least one of the source icons represents an audio source that includes multiple input channels.

6-7. (canceled)

8. The computer-implemented method of claim 1, further comprising:
receiving a second input modifying the position of one or more of the source icons; and
updating the gain control parameters of the audio mixer according to the positions of the manipulator and the source icons in response to the second input.

9. A computer program product, encoded on a non-transitory computer-readable medium, that when executed causes data processing apparatus to perform operations comprising:
displaying in a user interface multiple source icons and a manipulator, each source icon representing a separate one of multiple audio sources, each audio source having an output level, the manipulator and each source icon having a displayed position;
receiving a first input modifying the position of the manipulator in the user interface;
in response to receiving the first input, determining gain control parameters of an audio mixer to adjust the output levels of each of the multiple audio sources, the gain control parameters of the audio mixer determined according to a maximum gain factor and a perpendicular projection of the position of the manipulator onto each line of a plurality of lines, each line of the plurality of lines connecting a corresponding one of the positions of the source icons to a reference center;
receiving an input grouping one or more audio sources into distinct groups; and
assigning to each distinct group an independent manipulator element.

10. The computer program product of claim 9, wherein adjusting the output level of an audio source comprises:
setting a reference distance for each one of the audio sources to a distance between the corresponding source icon and the reference center;
determining a ratio between the reference distance of the source icon and a distance between the source icon and the perpendicular projection of the manipulator on the line passing through the source icon and the reference center; and
determining gain control parameters of the audio mixer to set the output level according to the ratio and the maximum gain factor.

11. The computer program product of claim 9, wherein adjusting the output level of an audio source comprises:
determining a first distance by a product of a second distance and the cosine of a difference between a first angle value and a second angle value, the second distance being defined by a distance between the manipulator and the reference center, the first angle value being defined by an angle between a reference axis through the reference center and the line through the reference center and the source icon, the second angle value being defined by an angle between the reference axis and a radial line through the reference center and the manipulator; and
determining gain control parameters of the audio mixer to set the output level according to the product of the first distance and the maximum gain factor.

12. The computer program product of claim 9, wherein the source icons are equidistant from the reference center.

13. The computer program product of claim 9, wherein at least one of the source icons represents an audio source that includes multiple input channels.

14-15. (canceled)

16. The computer program product of claim 9, further comprising:
receiving a second input modifying the position of one or more of the source icons; and
updating the gain control parameters of the audio mixer according to the positions of the manipulator and the source icons in response to the second input.

17. A system comprising:
one or more computers coupled to memory storing a computer program operable, when executed by the one or more computers, to cause the one or more computers to perform operations including:
displaying in a user interface multiple source icons and a manipulator, each source icon representing a separate one of multiple audio sources, each audio source having an output level, the manipulator and each source icon having a displayed position;
receiving a first input modifying the position of the manipulator in the user interface; and
in response to receiving the first input, determining gain control parameters of an audio mixer to adjust the output levels of each of the multiple audio sources, the gain control parameters of the audio mixer determined according to a maximum gain factor and a perpendicular projection of the position of the manipulator onto each line of a plurality of lines, each line of the plurality of lines connecting a corresponding one of the positions of the source icons to a reference center;
receiving an input grouping one or more audio sources into distinct groups; and
assigning to each distinct group an independent manipulator element.

18. The system of claim 17, wherein adjusting the output level of an audio source comprises:
setting a reference distance for each one of the audio sources to a distance between the corresponding source icon and the reference center;
determining a ratio between the reference distance of the source icon and a distance between the source icon and the perpendicular projection of the manipulator on the line passing through the source icon and the reference center; and
determining gain control parameters of the audio mixer to set the output level according to the ratio and the maximum gain factor.

19. The system of claim 17, wherein adjusting the output level of an audio source comprises:
determining a first distance by a product of a second distance and the cosine of a difference between a first angle value and a second angle value, the second distance being defined by a distance between the manipulator and the reference center, the first angle value being defined by an angle between a reference axis through the reference center and the line through the reference center and the source icon, the second angle value being defined by an angle between the reference axis and a radial line through the reference center and the manipulator; and
determining gain control parameters of the audio mixer to set the output level according to the product of the first distance and the maximum gain factor.

20. The system of claim 17, wherein the source icons are equidistant from the reference center.

21. The system of claim 17, wherein at least one of the source icons represents an audio source that includes multiple input channels.

22-23. (canceled)

24. The system of claim 17, further comprising:
receiving a second input modifying the position of one or more of the source icons; and
updating the gain control parameters of the audio mixer according to the positions of the manipulator and the source icons in response to the second input.

25. The computer-implemented method of claim 1, wherein moving the manipulator along a line representing the perpendicular projection of the position of the manipulator onto one line of the plurality of lines results in no modification of the output level of the audio source connected by the one line to the reference center.
